(19) United States
(12) Patent Application Publication
(10) Pub. No.: US 2022/0058874 A1
(43) Pub. Date: Feb. 24, 2022

(54) Automatic human body parameter generation method based on machine learning

(71) Applicant: SHANGHAI LINCTEX DIGITAL TECHNOLOGY CO, LTD., Shanghai (CN)

(72) Inventors: Likang LUO, Shanghai (CN); Luyuan WANG, Shanghai (CN); Xiaogang JING, Shanghai (CN); Chen LIU, Shanghai (CN); Ninghai HUANG, Shanghai (CN); Zexi SHAO, Shanghai (CN)

(21) Appl. No.: 17/520,595

(22) Filed: Nov. 5, 2021

Related U.S. Application Data
(63) Continuation of application No. PCT/CN2019/105296, filed on Sep. 11, 2019.

(30) Foreign Application Priority Data
May 7, 2019 (CN) 201910414893.7

(51) Int. Cl. G06T 17/20; G06T 17/10; G06K 9/00; G06T 7/60

(52) U.S. Cl. CPC G06T 17/205; G06T 7/60; G06K 9/00362; G06T 17/10

(57) ABSTRACT

A method of automatically generating human-body parameters using machine learning, including the following steps: initializing a converting program, inputs of which are accurate human-body parameters and outputs of which are general body-shape descriptions; inputting several groups of accurate human-body parameters into the converting program, so as to obtain various combinations of general body-shape descriptions, which are to be used as training sets for subsequent steps; carrying out training through machine learning by using the training sets obtained from Step (1), to obtain a mapping relationship between the general body-shape descriptions and parameters of a 3D human body model; recording gender, height, and weight information from a user and the user's responses to a series of preset general descriptive questions about body shape, and using the mapping relationship obtained from Step (3), to output accurate human-body parameters representing an actual human body of the user.

### CROSS-REFERENCE TO RELATED APPLICATIONS

This application is a bypass continuation application of PCT application no.: PCT/CN2019/105296. This application claims priorities from PCT Application No. PCT/CN2019/105296, filed Sep. 11, 2019, and from the Chinese patent application 201910414893.7 filed May 7, 2019, the contents of which are incorporated herein in the entirety by reference.

### TECHNICAL FIELD

The invention relates to the field of 3D human body reconstruction technology, in particular to an automatic human body parameter generation method based on machine learning.

### BACKGROUND TECHNOLOGY

During virtual dressing, it is often the case that a 3D human body model in line with the user's body shape shall be generated for the model to wear the garment and test the dressing effect. In most of the current 3D human body reconstruction methods, devices like the depth camera are utilized to scan the bodies of real users, and the 3D human body model is reconstructed based on the information obtained. This method is found with three defects: first, special devices are required to collect the human body information, which increases the device costs; second, the sensors shall be placed in an open and unblocked environment, restricting the site to some extent; third, the users shall pose as instructed to allow for rotational or multi-angle photographing so as to collect human body data, requiring some skills and even becoming an obstacle for some users.

In recent years, the development of machine learning greatly promotes the advancement of all computer science fields, leading to lots of open-sourced 3D model datasets about human bodies. The parameter mapping relationship of people with different body shapes can be obtained by means of machine learning, and it just takes some learning and training costs to efficiently get accurate results in future real applications, providing a new thought to the reconstruction of the 3D human body model.

### SUMMARY OF THE INVENTION

The invention aims to provide an automatic human body parameter generation method based on machine learning. The simple, efficient, and low-cost method provided by this invention can be utilized to rapidly generate accurate human body parameters close to the user's real body shape after inputting basic information about the user and answering the predefined questions.

An automatic human body parameter generation method based on machine learning, comprising the following steps:
(1) Initialize a converting program, with accurate human body parameters as the inputs and general body shape descriptions as the outputs, input several groups of accurate human body parameters into the said converting program in Step (1) to get different combinations of general body shape descriptions as the training sets for subsequent steps;
(2) Train by using the training sets from Step (1) through machine learning to get mapping relationship between general body shape descriptions and 3D human body model parameters;
(3) By inputting gender, specific height, and weight information, the users answer a series of preset general body shape-related descriptive questions (“yes” or “no”), and utilize the mapping relationship from Step (3) to rapidly output accurate human body parameters in line with the actual situation of the users.

In the said Step (1), the accurate data of the human body's different parts are within a certain range; with male neck shape as an example, the general body shape description is set in the converting program: when the neck circumference inputted is not more than 35 cm, the neck shape is “slightly thin”; when falling within 35-40 cm, the neck shape is “normal”; when greater than 40 cm, the neck shape is “slightly thick”. Likewise, with male waist shape as an example, the following general body shape description is presented in the converting program: when the waist-to-hip ratio is not more than 0.8, the waist shape is “sunken”; when greater than 0.8 and not more than 0.87, the waist shape is “straight”; when greater than 0.87 and not more than 0.93, the waist shape is “generally protruding”. In this way, all human body parameters inputted can be converted to get a group of general body shape descriptions about the human body model, namely, a group of answers to the body shape-related descriptive questions.

Further, for a certain group of human body measurements, a group of general human body descriptions can be outputted with the help of the converting program, such as “normal” neck shape, chest shape with “severely muscular”, “regular” shoulder shape, “straight” back, “slightly short” arm length, “generally protruding” waist shape, “flat” abdomen shape, “inverted triangular” body shape, “medium-sized” skeleton, and “normal” leg shape.

Further, when the model is being used in real life, the user shall answer a group of predefined body shape-related descriptive questions to get general body shape descriptions about the user.

In the said Step (3), every 3D human body model is equipped with a group of human body measurements; to get a 3D human body model in line with the user's real body shape, general body shape descriptions given by the user shall be correlated with human body measurements of corresponding body shapes, which are called mapping relationship.

### DESCRIPTION OF FIGURES

FIG. 1 presents some general descriptions and judgment conditions in the converting program;

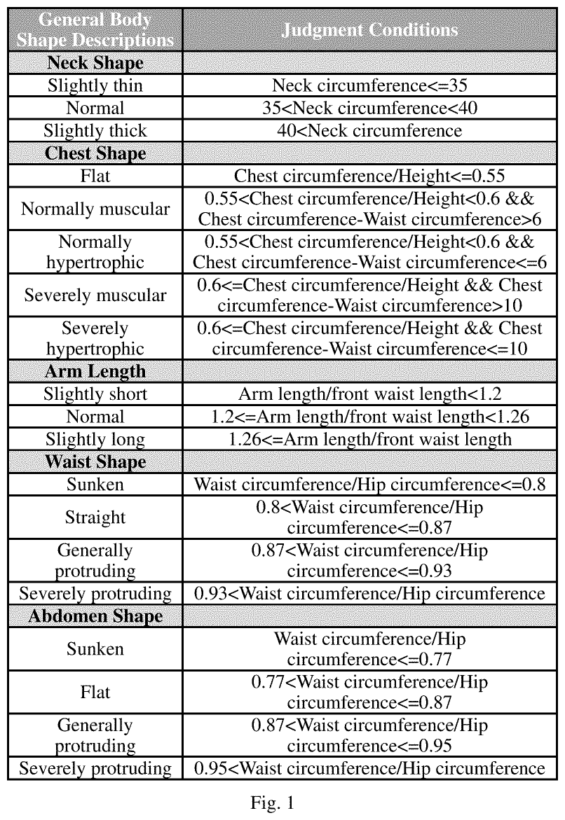

FIG. 2 presents some predefined questions (about females) on general human body descriptions provided in this invention;

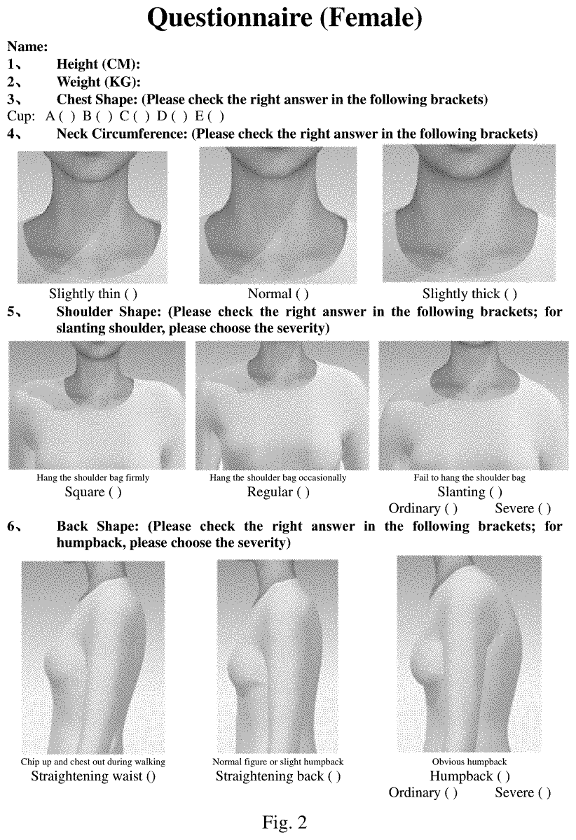

### DETAILED DESCRIPTION OF THE INVENTION EMBODIMENTS

Next, the technical solution in this invention will be further detailed in conjunction with figures and embodiments.
(1) Initialize a converting program, with accurate human body parameters as the inputs and general body shape descriptions as the outputs; input several groups of accurate human body parameters into the converting program to get different combinations of general body shape descriptions as the training sets for subsequent steps;
(2) Train by using the training sets from Step (1) through machine learning to get mapping relationship between general body shape descriptions and 3D human body model parameters;
(3) By inputting gender, specific height, and weight information, the users answer a series of preset general body shape-related descriptive questions (“yes” or “no”), and utilize the mapping relationship from Step (3) to rapidly output accurate human body parameters in line with the actual situation of the users.

In the said Step (1), the accurate data of the human body's different parts are within a certain range; with male neck shape as an example, the general body shape description is set in the converting program: when the neck circumference inputted is not more than 35 cm, the neck shape is “slightly thin”; when falling within 35-40 cm, the neck shape is “normal”; when greater than 40 cm, the neck shape is “slightly thick”. Likewise, with male waist shape as an example, the following general body shape description is presented in the converting program: when the waist-to-hip ratio is not more than 0.8, the waist shape is “sunken”; when greater than 0.8 and not more than 0.87, the waist shape is “straight”; when greater than 0.87 and not more than 0.93, the waist shape is “generally protruding”. In this way, all human body parameters inputted can be converted to get a group of general body shape descriptions about the human body model, namely, a group of answers to the body shape-related descriptive questions.

(1-1) For a certain group of human body measurements, a group of general human body descriptions can be outputted with the help of the converting program, such as “normal” neck shape, chest shape with “severely muscular”, “regular” shoulder shape, “straight” back, “slightly short” arm length, “generally protruding” waist shape, “flat” abdomen shape, “inverted triangular” body shape, “medium-sized” skeleton, and “normal” leg shape.

(1-2) When the model is being used in real life, the user shall answer a group of predefined body shape-related descriptive questions to get general body shape descriptions about the user.

In the said Step (3), every 3D human body model is equipped with a group of human body measurements; to get a 3D human body model in line with the user's real body shape, general body shape descriptions given by the user shall be correlated with human body measurements of corresponding body shapes, which are called mapping relationship.

Above are detailed descriptions about this invention, but the embodiments of this invention are not limited to the above ones, and other alterations, replacements, combinations, and simplifications made under the guidance of the core idea of this invention shall also be included in the protection range of this invention.

1. A method of automatically generating human-body parameters using machine learning, comprising the following steps:
(1) initializing a converting program, inputs of which are accurate human-body parameters and outputs of which are general body-shape descriptions; inputting several groups of accurate human-body parameters into the converting program, so as to obtain various combinations of general body-shape descriptions, which are to be used as training sets for subsequent steps;
(2) carrying out training through machine learning by using the training sets obtained from Step (1), to obtain a mapping relationship between the general body-shape descriptions and parameters of a 3D human body model;
(3) recording gender, height, and weight information from a user and the user's responses to a series of preset general descriptive questions about body shape, and using the mapping relationship obtained from Step (3), to output accurate human-body parameters representing an actual human body of the user.

2. The method of claim 1, wherein accurate data of different parts of a human body are within a certain range; for a neck shape of a male, the general body-shape descriptions are set in the converting program as follows: when an inputted neck circumference is not more than 35 cm, the neck shape is “slightly thin”; when the inputted neck circumference is between 35 cm and 40 cm, the neck shape is “normal”; when the inputted neck circumference is greater than 40 cm, the neck shape is “slightly thick”; for a waist shape of the male, the general body-shape descriptions are set in the converting program as follows: when a waist-to-hip ratio is not more than 0.8, the waist shape is “sunken”; when the waist-to-hip ratio is greater than 0.8 and not more than 0.87, the waist shape is “straight”; when waist-to-hip ratio is greater than 0.87 and not more than 0.93, the waist shape is “generally protruding”; and all human-body parameters inputted are converted to obtain a group of the general body-shape descriptions about the 3D human body model, wherein the group of the general body-shape descriptions are a group of answers to the descriptive questions about body shape.

3. The method of claim 2, wherein for a certain group of human body measurements, the group of general human body descriptions are outputted with the help of the converting program.

4. The method of claim 2, wherein the user answers a group of predefined body shape-related descriptive questions to obtain general body shape descriptions about the user.

5. The method of claim 1, wherein the 3D human body model further comprises a group of human body measurement data; general body-shape descriptions given by the user are correlated with human body measurement data of a corresponding body shape to obtain a 3D human body model in line with the user's real body shape.
